(19) United States
(12) Patent Application Publication
(10) Pub. No.: US 2024/0244773 A1
(43) Pub. Date: Jul. 18, 2024

(54) ELECTRONIC DEVICE

(71) Applicant: Panasonic Intellectual Property Management Co., Ltd., Osaka (JP)

(72) Inventors: Shingo ARAKAWA, Osaka (JP); Keiichiro YOHARA, Osaka (JP); Fuyuto NAKAMURA, Hyogo (JP); Noriyuki MAKI, Osaka (JP); Ryota MORIKAWA, Osaka (JP); Tsunekazu IKATSU, Hyogo (JP)

(73) Assignee: Panasonic Intellectual Property Management Co., Ltd., Osaka (JP)

(21) Appl. No.: 18/622,956

(22) Filed: Mar. 31, 2024

Related U.S. Application Data
(63) Continuation of application No. PCT/JP22/35251, filed on Sep. 21, 2022.

(30) Foreign Application Priority Data
Oct. 7, 2021 (JP) 2021-165509

(51) Int. Cl. H05K 5/02; H01M 50/247; H01M 50/289; H05K 5/00

(52) U.S. Cl. CPC H05K 5/0214; H01M 50/247; H01M 50/289; H05K 5/0086; H01M 2220/30

(57) ABSTRACT

An electronic device of the present disclosure includes a battery, a housing that houses the battery and includes a plurality of through holes in an area where the battery is disposed, and a film member that is disposed in the housing, closes the plurality of through holes, and melts from heat.

### BACKGROUND

### 1. Technical Field

The present disclosure relates to an electronic device.

### 2. Description of the Related Art

Patent Literature (PTL) 1 discloses a battery module. The battery module described in PTL 1 includes a battery cell, a module case, and a film member. The module case accommodates a plurality of battery cells. Inside the module case, internal cooling channels are formed on both sides of the battery cells. At least one opening facing the internal cooling channel of the module case is provided on both side surfaces of the module case. The film member is attached to both side surfaces of the module case so as to cover at least one opening. The film member melts at a predetermined temperature or higher to open at least one opening.
PTL 1 is Japanese Translation Publication No. 2021-502665 of PCT Publication WO2020/075962.

### SUMMARY

An object of the present disclosure is to provide an electronic device capable of improving safety.

An electronic device according to one aspect of the present disclosure includes:
a battery;
a housing that houses the battery and includes a plurality of through holes in an area where the battery is disposed; and
a film member that is disposed in the housing, closes the plurality of through holes, and melts from heat.

The present disclosure can provide an electronic device capable of improving safety.

### BRIEF DESCRIPTION OF THE DRAWINGS

FIG. 1 is a schematic perspective view of an example of an electronic device of a first exemplary embodiment according to the present disclosure.

FIG. 2 is a schematic perspective view illustrating a state in which a battery is taken out in the electronic device of FIG. 1.

FIG. 3 is a schematic exploded perspective view of an example of the battery.

FIG. 4 is a schematic bottom view of the electronic device of FIG. 1.

FIG. 5 is a schematic enlarged view of a Z1 portion of the electronic device of FIG. 4.

FIG. 6 is a schematic enlarged view of a Z2 portion of the electronic device of FIG. 5.

FIG. 7 is a schematic cross-sectional view of the electronic device of FIG. 4 taken along line A-A.

FIG. 8 is a schematic partially exploded view illustrating an example of disposition of film members.

FIG. 9A is a schematic diagram for describing an example of an operation of the electronic device according to the first exemplary embodiment of the present disclosure.

FIG. 9B is a schematic diagram for describing an example of an operation of the electronic device according to the first exemplary embodiment of the present disclosure.

### DETAILED DESCRIPTION

### Background of Present Disclosure

In the battery module described in PTL 1, at least one opening is provided in a module case, and the at least one opening is covered with a film member. When a high-temperature situation occurs due to abnormal heat generation of the battery cell, the film member melts because of the heat and opens the at least one opening. With this configuration, high-temperature gas, flame, and the like are discharged to the outside of the battery module.

However, in the case of an electronic device in which a battery is housed inside, an opening may be closed by a housing of the electronic device. For example, in the case of a highly-airtight electronic device having dustproofness and waterproofness, the battery is covered with the housing of the electronic device and is not exposed to the outside of the housing of the electronic device. When the battery module described in PTL 1 is used in such an electronic device, the opening is not opened to the outside of the housing of the electronic device even when the film member melt from the heat. Thus, high-temperature gas, flame, and the like cannot be discharged to the outside of the housing of the electronic device.

In this manner, in an electronic device in which a battery is housed inside, there is a problem that high-temperature gas, flame, and the like cannot be discharged to the outside of the housing of the electronic device even when the battery module described in PTL 1 is used.

To solve the above problem, the inventors of the present invention have found a configuration in which a plurality of through holes are provided in a housing of an electronic device and the plurality of through holes are closed by a film member that melts from the heat, and have reached the present disclosure.

An electronic device according to a first aspect of the present disclosure includes a battery, a housing that houses the battery and is provided with a plurality of through holes in an area where the battery is disposed, and a film member that is disposed in the housing, closes the plurality of through holes, and melts from heat.

Such a configuration can improve safety.

In an electronic device according to a second aspect of the present disclosure, each of the plurality of through holes may have a slit shape having a longitudinal direction and a lateral direction in plan view.

Such a configuration can improve safety while suppressing a decrease in mechanical strength.

In an electronic device according to a third aspect of the present disclosure, the plurality of through holes may be provided at a first interval in the longitudinal direction and provided at a second interval smaller than the first interval in the lateral direction in plan view.

Such a configuration can further improve safety.

In an electronic device according to a fourth aspect of the present disclosure, the battery may include a plurality of battery cells, and the plurality of through holes may be provided at positions overlapping the plurality of battery cells in plan view.

Such a configuration, with which a through hole can be provided near the battery cell, can further improve safety.

In an electronic device according to a fifth aspect of the present disclosure, the housing may include a partition outer wall that partitions the plurality of through holes, and the partition outer wall may have an area larger than an opening area of the plurality of through holes in plan view.

Such a configuration can improve safety while suppressing a decrease in mechanical strength.

In an electronic device according to a sixth aspect of the present disclosure, the battery may include a partition wall disposed between two adjacent battery cells among the plurality of battery cells, and the partition wall may be disposed at a position overlapping the partition outer wall in plan view.

Such a configuration can further improve safety.

In an electronic device according to a seventh aspect of the present disclosure, the film member may be disposed inside the housing.

Such a configuration, with which the film member is disposed at a position where the film member easily melts from the heat from the battery cell, can further improve safety.

In an electronic device according to an eighth aspect of the present disclosure, a channel extending along the plurality of through holes may be provided between the battery and the housing.

Such a configuration can further improve safety.

In an electronic device according to a ninth aspect of the present disclosure, the channel may include a first channel closer to the plurality of through holes than the battery and a second channel farther from the plurality of through holes than the battery, and the first channel may have a width smaller than a width of the second channel.

Such a configuration can further improve safety.

In an electronic device according to a tenth aspect of the present disclosure, the battery may include a battery case defining an outer contour of the battery, and the film member may have a melting point lower than a melting point of the battery case.

Such a configuration can further improve safety.

In an electronic device according to an eleventh aspect of the present disclosure, the film member may include a film and/or an adhesive tape.

Such a configuration can further improve safety.

Hereinafter, exemplary embodiments of the present disclosure will be described with reference to the accompanying drawings. In each drawing, each element is exaggerated in order to facilitate the description.

In this specification, the terms “first”, “second”, and the like are only used for description, and should not be understood as expressing or implying relative importance or a rank of a technical feature. Features limited to “first” and “second” are intended to express or imply the inclusion of one or more such features.

### First Exemplary Embodiment

### [Overall Configuration of Electronic Device]

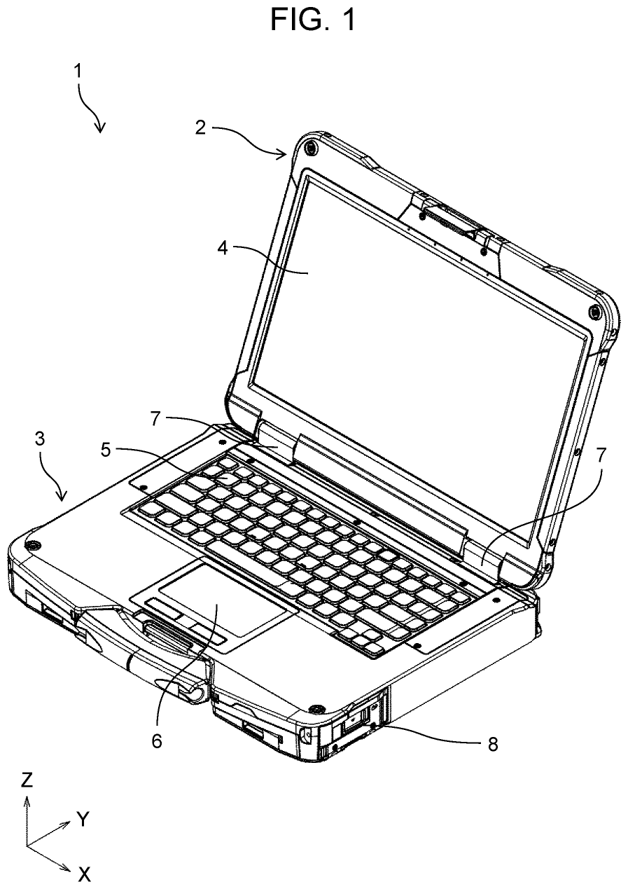

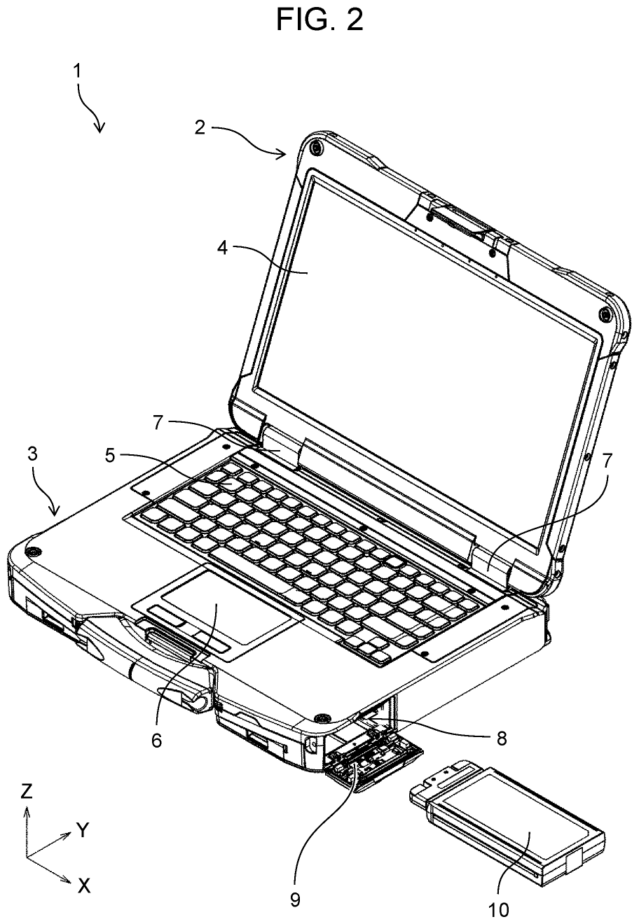

FIG. 1 is a schematic perspective view of an example of electronic device 1 of a first exemplary embodiment according to the present disclosure. FIG. 2 is a schematic perspective view illustrating a state in which battery 10 is taken out in electronic device 1 of FIG. 1. X-, Y-, and Z-directions in the drawing indicate a width direction, a depth direction, and a height direction of electronic device 1, respectively. The example illustrated in FIG. 2 illustrates a state in which battery 10 on one side in the width direction (X-direction) of electronic device 1 is taken out. In the present exemplary embodiment, battery 10 can also be housed on the other side in the width direction (X-direction) of electronic device 1. That is, electronic device 1 can house two batteries 10.

As illustrated in FIGS. 1 and 2, electronic device 1 is a notebook personal computer (laptop PC). Electronic device 1 includes first housing 2 and second housing 3. Each of first housing 2 and second housing 3 has a thin box-shaped outer contour and has a rectangular shape.

First housing 2 houses display 4. Display 4 is, for example, a liquid crystal. A display surface of display 4 is exposed from first housing 2. First housing 2 also houses a camera, an antenna, and the like.

Second housing 3 houses an input unit. The input unit is, for example, keyboard 5 and touch pad 6. The input unit is exposed from second housing 3. In the present specification, keyboard 5 and touch pad 6 may be referred to as input units 5, 6. A circuit such as a CPU or a memory, battery 10, and the like are housed inside second housing 3. In the present exemplary embodiment, battery 10 is housed inside second housing 3 without being exposed from second housing 3.

Specifically, second housing 3 includes housing unit 8 that houses battery 10. Housing unit 8 encloses battery 10 in second housing 3. Housing unit 8 holds battery 10 inside second housing 3 without exposing the battery from second housing 3. Housing unit 8 is defined by, for example, an inner wall of second housing 3. Housing unit 8 may include a member other than the inner wall of second housing 3.

Housing unit 8 has lid 9 provided on a side wall of second housing 3. By opening lid 9, battery 10 can be taken in and out of housing unit 8. By closing lid 9, the inside of housing unit 8 and the outside of second housing 3 can be separated from each other.

First housing 2 and second housing 3 are connected via hinge 7. Hinge 7 rotatably connects first housing 2 and second housing 3. Hinge 7 allows first housing 2 and/or second housing 3 to rotate and bring electronic device 1 into an open state or a closed state. The “open state” means a state in which first housing 2 and second housing 3 are separated from each other and display 4 and input units 5, 6 are exposed. The “closed state” means a state in which first housing 2 and second housing 3 are disposed to face each other, display 4 and input units 5, 6 face each other, and display 4 and input units 5, 6 are not exposed.

First housing 2 and second housing 3 are made of a metal material. For example, first housing 2 and second housing 3 are made of magnesium alloy.

### [Battery]

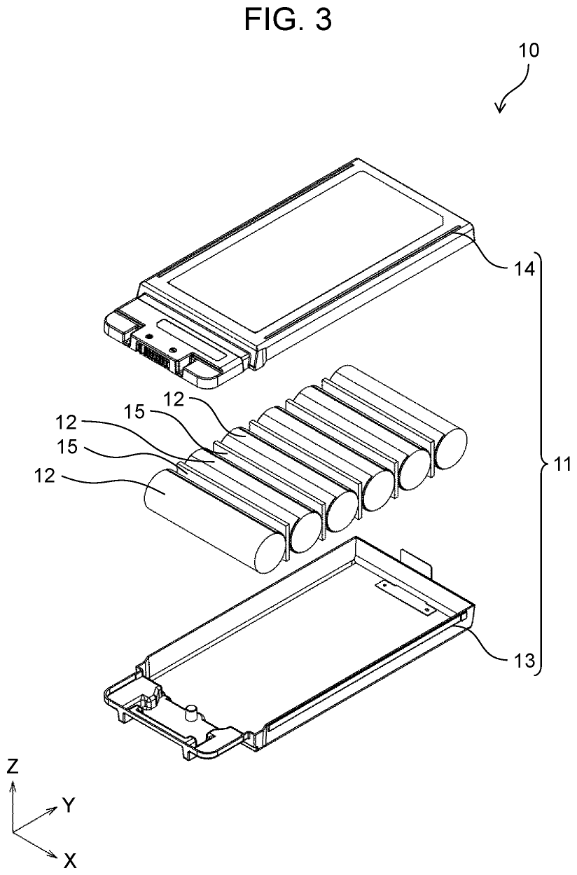

FIG. 3 is a schematic exploded perspective view of an example of battery 10.

As illustrated in FIG. 3, battery 10 includes battery case 11 and a plurality of battery cells 12.

Battery case 11 is a case that defines an outer contour of battery 10 and houses the plurality of battery cells 12. Battery case 11 includes first case 13 and second case 14. First case 13 and second case 14 are formed in a recessed shape, and are connected to each other to form a space for housing the plurality of battery cells 12 therein. In the present exemplary embodiment, first case 13 forms the bottom side of battery case 11, and second case 14 forms the top side of battery case 11.

The temperature at which battery case 11 burns down is, for example, from 245° C. to 280° C. inclusive. The “temperature at which battery case 11 burns down” means a temperature at which the battery case melts and deforms. For example, the “temperature at which battery case 11 burns down” may be a melting point. Battery case 11 is formed of, for example, plastic. Examples of the plastic material forming battery case 11 include polycarbonate.

The plurality of battery cells 12 are housed in battery case 11. The plurality of battery cells 12 are electrically connected to each other. In the present exemplary embodiment, each of the plurality of battery cells 12 is a cylindrical cell.

In addition, battery 10 has a plurality of partition walls 15 disposed between the plurality of battery cells 12. Partition wall 15 is disposed between adjacent battery cells 12. Partition wall 15 thermally shields between adjacent battery cells 12. Partition wall 15 has a melting point higher than that of battery case 11. The melting point of partition wall 15 is, for example, more than or equal to 1200° C. Partition wall 15 is made of a material having a heat insulating property. Specifically, partition wall 15 is made of a material having lower thermal conductivity than battery case 11. Partition wall 15 is formed of, for example, a mica plate.

At the time of abnormal heat generation such as generation of flame or high-temperature gas from battery cell 12, partition wall 15 having a melting point higher than that of battery case 11 is less likely to melt as compared with battery case 11. This makes it possible to suppress movement of flame or high-temperature gas to adjacent battery cell 12 because of partition wall 15 when flame or high-temperature gas is generated in battery cell 12. In addition, partition wall 15 having a lower thermal conductivity than battery case 11 can suppress heat conduction as compared with battery case 11. This makes it possible to suppress heat conduction of the heat of battery cell 12 that is abnormally generating heat to adjacent battery cell 12.

### [Detailed Structure of Electronic Device]

Next, a detailed structure of a portion in which battery 10 is housed in electronic device 1 will be described.

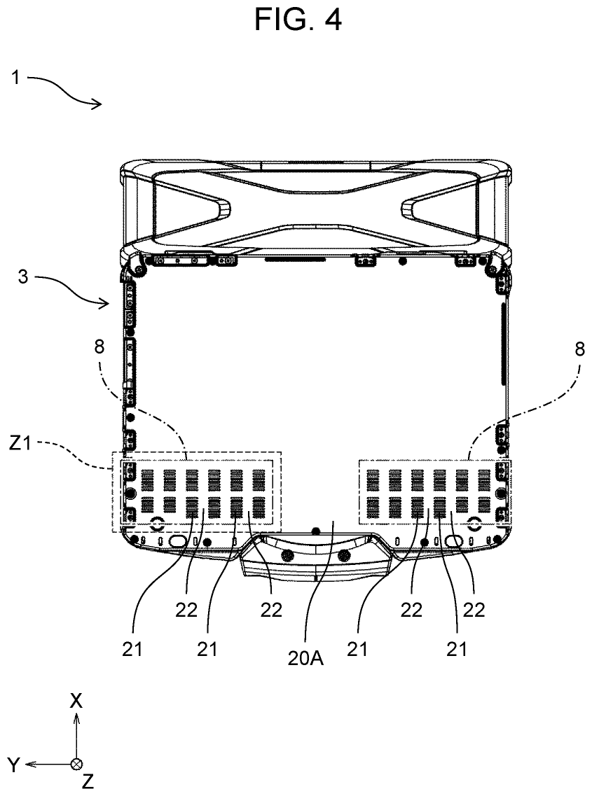

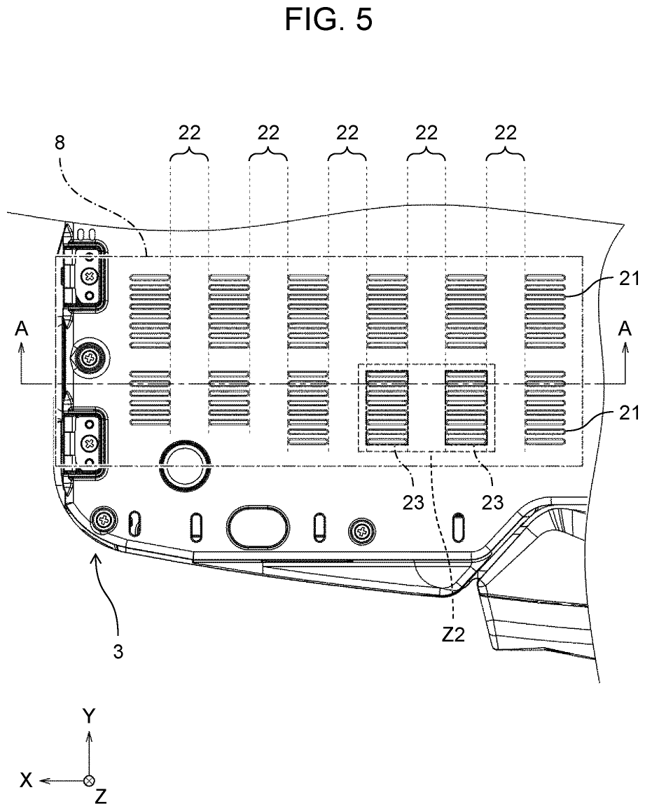

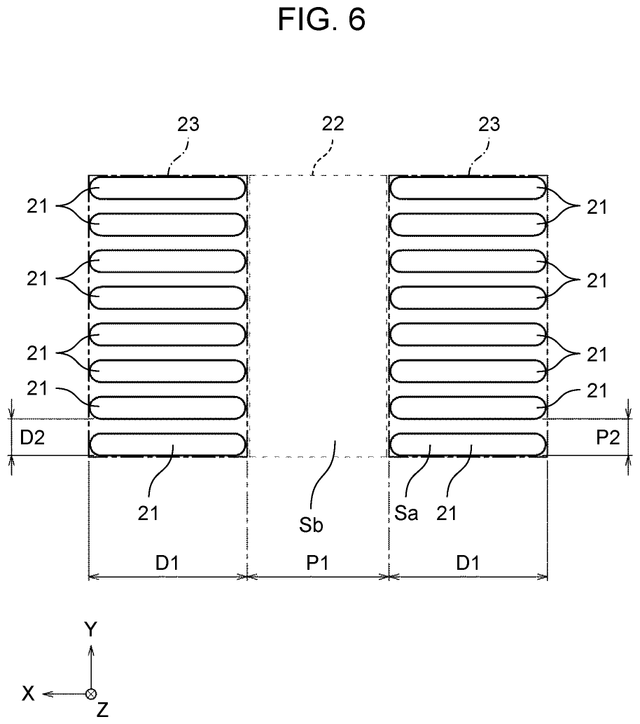

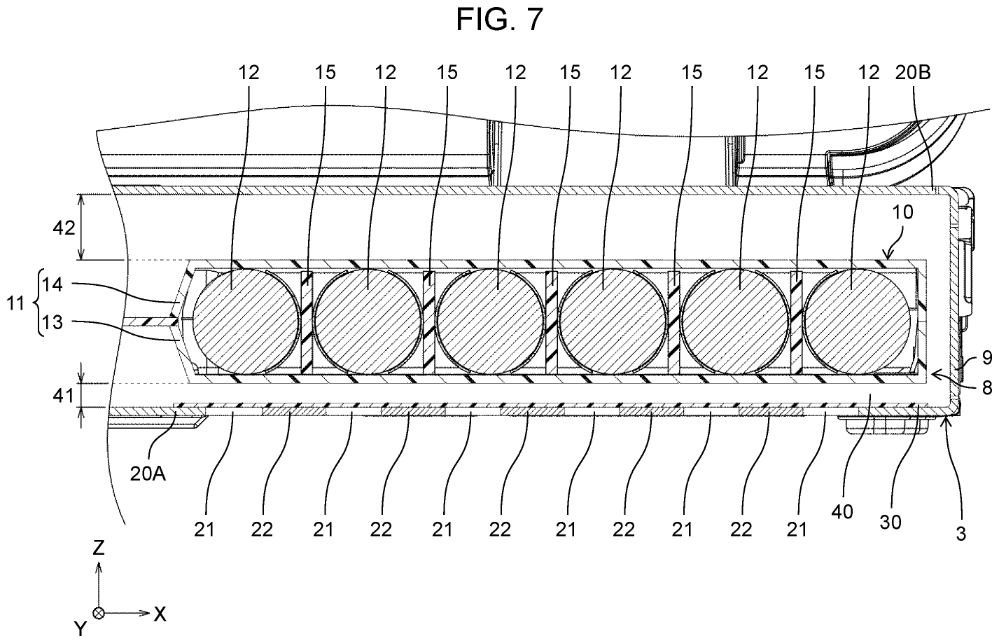

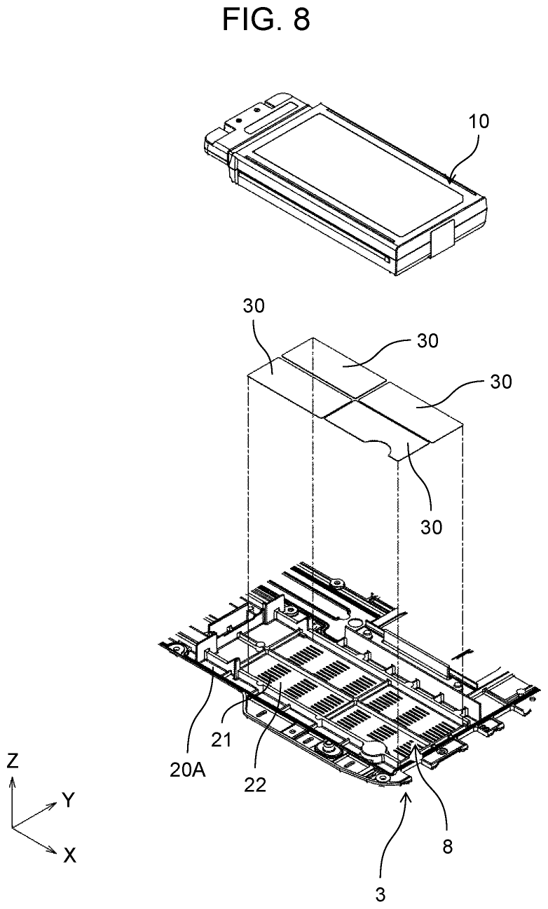

FIG. 4 is a schematic bottom view of electronic device 1 of FIG. 1. FIG. 5 is a schematic enlarged view of a Z1 portion of electronic device 1 of FIG. 4. FIG. 6 is a schematic enlarged view of a Z2 portion of electronic device 1 of FIG. 5. FIG. 7 is a schematic cross-sectional view of electronic device 1 of FIG. 4 taken along line A-A. FIG. 8 is a schematic partially exploded view illustrating an example of disposition of film members 30. A region indicated by a dash-dotted line in FIGS. 4 and 5 indicates a region where housing unit 8 is formed in plan view. In addition, “in plan view” means viewing from the height direction (Z-direction) of electronic device 1.

In the present exemplary embodiment, second housing 3 includes bottom case 20A and top case 20B. Bottom case 20A forms the bottom side of second housing 3, and top case 20B forms the top side of second housing 3. Input units such as keyboard 5 and touch pad 6 are disposed in top case 20B. Bottom case 20A is disposed on the opposite side of top case 20B.

As illustrated in FIGS. 4 to 8, a plurality of through holes 21 are provided in second housing 3 of electronic device 1. The plurality of through holes 21 are provided in bottom case 20A. The plurality of through holes 21 are provided in an area where battery 10 is disposed. Specifically, the plurality of through holes 21 are provided in the area overlapping the region where housing unit 8 is formed in plan view.

In the present exemplary embodiment, two housing units 8 are provided to face each other in the width direction (X-direction) of second housing 3. Thus, the plurality of through holes 21 are provided on both sides of bottom case 20A in the width direction (X-direction) except for a central portion. Two housing units 8 may be connected to each other inside thereof.

Second housing 3 has partition outer wall 22 that partitions the plurality of through holes 21. Partition outer wall 22 is provided in bottom case 20A like the plurality of through holes 21. Partition outer wall 22 partitions the plurality of through holes 21 adjacent in the width direction (X-direction) of second housing 3. Specifically, partition outer wall 22 is provided at a position overlapping a region where battery 10 is disposed in plan view, and is provided between the plurality of through holes 21 adjacent in the width direction (X-direction) of second housing 3. Partition outer wall 22 is formed of a continuous outer wall extending in the depth direction (Y-direction) of second housing 3. That is, partition outer wall 22 is not provided with through hole 21.

As illustrated in FIGS. 7 and 8, electronic device 1 includes film member 30 disposed in second housing 3 in such a manner as to close the plurality of through holes 21. Film member 30 is disposed inside second housing 3. Film member 30 closes the plurality of through holes 21 to achieve dustproofness and waterproofness of electronic device 1. That is, film member 30 prevents dust and water from entering the inside of second housing 3 through the plurality of through holes 21 during normal use of electronic device 1.

Film member 30 is formed of a member that melts from the heat. For example, at the time of abnormal heat generation such as generation of flame or high-temperature gas from battery 10, film member 30 melts from the heat, whereby the plurality of through holes 21 can be opened. This makes it possible to discharge flame and high-temperature gas generated from battery 10 to the outside of second housing 3 through the plurality of through holes 21.

The melting point of film member 30 is higher than the maximum housing temperature assumed at the time of normal use of electronic device 1, and is lower than the melting point of flame or high-temperature gas. For example, the melting point of film member 30 should be from 100° C. to 550° C. inclusive. The temperature at which film member 30 burns down is preferably equal to or lower than the temperature at which battery case 11 burns down.

For example, the thickness of film member 30 is less than or equal to 250 μm. Preferably, the thickness of the film member is 50 μm.

For example, film member 30 can be formed of polyethylene terephthalate (PET), polyethylene (PE), polypropylene (PP), or the like.

In the present exemplary embodiment, film member 30 includes a PET film and an adhesive tape. Film member 30 is attached to the inner side of second housing 3 with an adhesive tape. In the present exemplary embodiment, the plurality of film members 30 are disposed inside second housing 3.

Film member 30 is not limited to a member formed of a PET film and an adhesive tape. Film member 30 is not limited as long as the film member has a film and/or an adhesive tape. For example, film member 30 may be formed of a film without having an adhesive tape. In this case, one surface of the film may be an adhesive surface. Alternatively, film member 30 may be formed of an adhesive tape without having a film.

Next, through hole 21 will be described in detail.

As illustrated in FIGS. 4 to 6, each of the plurality of through holes 21 has a slit shape having a longitudinal direction and a lateral direction in plan view. In the present exemplary embodiment, the longitudinal direction is the X-direction, and the lateral direction is the Y-direction.

As illustrated in FIG. 6, for example, first dimension D1 of through hole 21 in the longitudinal direction is from 5 mm to 10 mm inclusive, and second dimension D2 of through hole 21 in the lateral direction is from 0.45 mm to 0.9 mm inclusive. Preferably, first dimension D1 is 10 mm, and second dimension D2 is 0.9 mm. The size and shape of through hole 21 are not limited to these. The size of through hole 21 is not limited as long as the size is more than or equal to 3/10 times the surface area of the housing portion in which battery cell 12 of battery 10 is housed and sufficient mechanical strength of the housing is maintained. Through hole 21 may be provided at a position overlapping battery cell 12 in plan view.

The plurality of through holes 21 are provided at first interval P1 in the longitudinal direction and at second interval P2 in the lateral direction in plan view. Second interval P2 is smaller than first interval P1. For example, first interval P1 is 10 mm, and second interval P2 is from 1.8 mm to 3 mm inclusive, preferably 2.5 mm. The interval between through holes 21 is not limited to these values. First interval P1 and second interval P2 are not limited as long as the they are more than or equal to 3/10 times the surface area of the housing portion in which battery cell 12 of battery 10 is housed and sufficient mechanical strength of the housing is maintained. Through hole 21 is provided at a position overlapping battery cell 12 in plan view.

The plurality of through holes 21 are provided at positions overlapping the plurality of battery cells 12 of battery 10 in plan view. That is, the plurality of through holes 21 are provided at positions facing the plurality of battery cells 12 in plan view. For example, first interval P1 of the plurality of through holes 21 may be substantially equal to the disposition interval of the plurality of battery cells 12. Here, “substantially” includes an error within 10%, and preferably includes an error within 5%. With this configuration, the through hole 21 can be provided close to battery cell 12, and thus flame or high-temperature gas is easily discharged from through hole 21 when flame or high-temperature gas is generated from battery cell 12.

In the present exemplary embodiment, the plurality of through holes 21 have substantially the same shape and size.

A region formed by the plurality of through holes 21 provided at second interval P2 in the lateral direction (Y-direction) of through hole 21 is defined as opening region 23. Opening region 23 is a region surrounding the plurality of through holes 21 provided at second interval P2 in the lateral direction (Y-direction) of through hole 21.

Second housing 3 is provided with a plurality of opening regions 23. The plurality of opening regions 23 are provided at first interval P1. In the present exemplary embodiment, 12 opening regions 23 are provided for one battery 10. The number of opening regions 23 is not limited to this number.

Next, partition outer wall 22 will be described in detail.

As illustrated in FIG. 6, partition outer wall 22 is provided between the plurality of through holes 21 adjacent to each other in the width direction (X-direction) of second housing 3. In other words, partition outer wall 22 is formed in a region sandwiched by the plurality of opening regions 23 in the width direction (X-direction) of second housing 3. Partition outer wall 22 has area Sb larger than opening area Sa of the plurality of through holes 21 in plan view. Specifically, in plan view, area Sb of partition outer wall 22 is larger than opening area of opening region 23. The opening area Sa of opening region 23 is the sum of opening area of each of the plurality of through holes 21 in plan view. This can secure the mechanical strength of second housing 3.

As illustrated in FIG. 7, partition outer wall 22 is provided between the plurality of battery cells 12 of battery 10 in plan view. In the present exemplary embodiment, partition wall 15 is disposed between the plurality of battery cells 12. Thus, partition outer wall 22 is disposed at a position overlapping partition wall 15 of battery 10 in plan view. In other words, partition wall 15 is disposed at a position overlapping partition outer wall 22 in plan view. This makes it possible to prevent flame from spreading and heat from being transferred between adjacent battery cells 12.

Next, channel 40 between battery 10 and second housing 3 will be described.

As illustrated in FIG. 7, channel 40 extending to the plurality of through holes 21 is provided between battery 10 and second housing 3. Channel 40 is formed by a gap between battery 10 and second housing 3. Specifically, channel 40 is defined by an outer wall of battery case 11 and an inner wall of second housing 3. Channel 40 is formed in such a manner as to surround the outer wall of battery case 11.

Channel 40 includes first channel 41 on the side where the plurality of through holes 21 are positioned and second channel 42 on the side opposite to the side where the plurality of through holes 21 are positioned. First channel 41 is smaller than second channel 42.

First channel 41 is formed by a gap formed between first case 13 of battery case 11 and bottom case 20A of second housing 3. Second channel 42 is formed by a gap formed between second case 14 of battery case 11 and top case 20B of second housing 3.

For example, the channel width of first channel 41 is more than or equal to ¼ times and less than or equal to 1 time the channel width of second channel 42. Preferably, the channel width of first channel 41 is more than or equal to 0.9 mm at the narrowest portion and less than or equal to 5.1 mm at the widest portion, and the channel width of second channel 42 is more than or equal to 0.4 mm at the narrowest portion and less than or equal to 6 mm at the widest portion. The channel width means a dimension in the height direction (Z-direction) of electronic device 1. When the channel widths of first channel 41 and second channel 42 are too narrow, high-temperature gas cannot pass therethrough and does not reach film member 30. When the channel widths of first channel 41 and second channel 42 are too wide, high-temperature gas is retained and does not reach film member 30 in some cases. When the channel widths of first channel 41 and second channel 42 are at least within the above numerical ranges, it is possible to suppress the retention of high-temperature gas.

When flame or high-temperature gas is generated in battery 10, channel 40 guides the flame or high-temperature gas toward the plurality of through holes 21. That is, the flame or high-temperature gas generated in battery 10 moves toward the plurality of through holes 21 through channel 40. In addition, since first channel 41 is smaller than second channel 42, the flow velocity of the flame or high-temperature gas flowing through first channel 41 can be made larger than the flow velocity in the second channel. This makes it possible to quickly discharge flame and high-temperature gas from the plurality of through holes 21.

### [Operation]

Next, an example of an operation in electronic device 1 will be described.

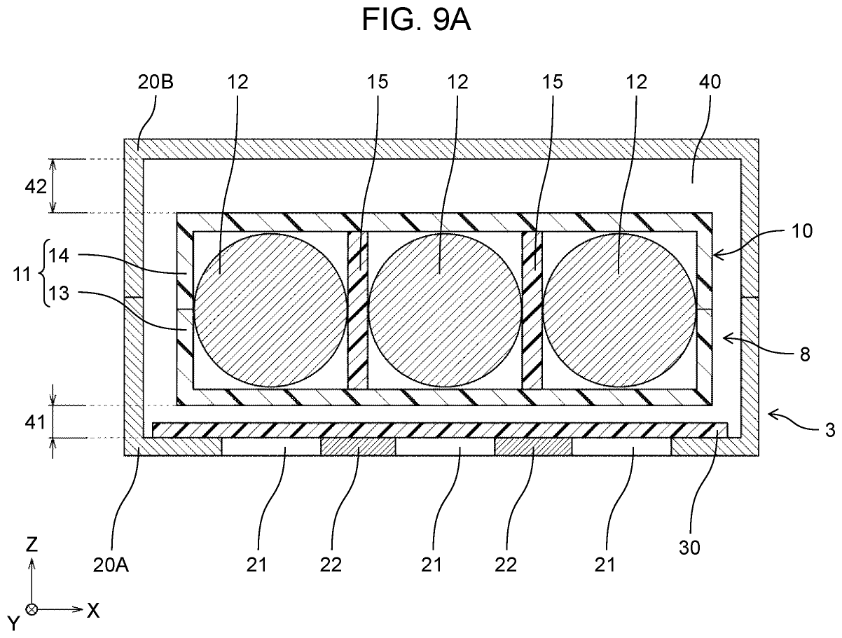

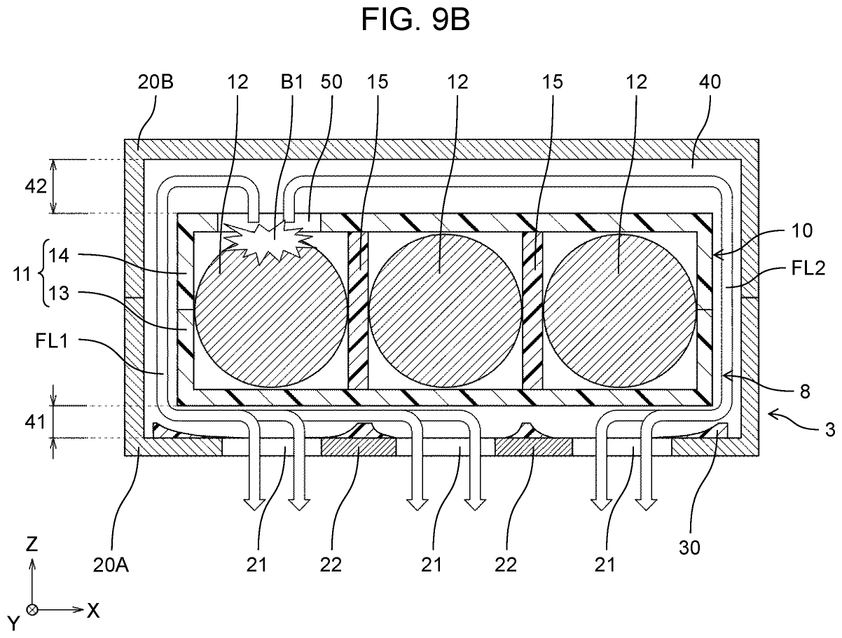

FIGS. 9A and 9B are schematic diagrams for describing an example of the operation of electronic device 1 according to the first exemplary embodiment of the present disclosure. FIG. 9A illustrates an example of an operation during normal use of electronic device 1. FIG. 9B illustrates an example of an operation when battery 10 generates abnormal heat in electronic device 1. FIGS. 9A and 9B illustrate the internal configuration of electronic device 1 in a simplified manner to facilitate the description.

As illustrated in FIG. 9A, during normal use of electronic device 1, the plurality of through holes 21 are closed by film member 30. Therefore, dust and water are prevented from entering the inside of second housing 3 through the plurality of through holes 21. That is, dustproofness and waterproofness of electronic device 1 are secured by film member 30 closing the plurality of through holes 21.

As illustrated in FIG. 9B, at the time of abnormal heat generation in which battery cell 12 is ignited in battery 10 and flame B1 and/or high-temperature gas is generated, battery case 11 melts from the heat of flame B1 and/or high-temperature gas generated in battery cell 12, and hole 50 is formed in battery case 11. The flame B1 and/or high-temperature gas flows from hole 50 through channel 40 toward the plurality of through holes 21. Specifically, as indicated by arrows FL1, FL2 in FIG. 9B, flame B1 and/or high-temperature gas flows in channel 40 so as to go around the outer wall of battery case 11.

When flame B1 and/or high-temperature gas reaches first channel 41 provided with the plurality of through holes 21, film member 30 melts from the heat of flame B1 and/or high-temperature gas. When film member 30 melts, the plurality of through holes 21 open. This causes flame B1 and/or high-temperature gas to be discharged from the plurality of through holes 21 to the outside of second housing 3.

### [Effects]

According to electronic device 1 of the first exemplary embodiment, the following effects can be obtained.

Electronic device 1 includes battery 10, housing 3, and film member 30. Housing 3 houses battery 10 therein. A plurality of through holes 21 are provided with in an area in housing 3 where battery 10 is disposed. Film member 30 is disposed in housing 3, closes the plurality of through holes 21, and melts from the heat.

Such a configuration can improve the safety of electronic device 1. Further, the safety of electronic device 1 can be improved with an inexpensive configuration. Specifically, at the time of normal used, film member 30 closing the plurality of through holes 21 can secure dustproofness and waterproofness. At the time of abnormal heat generation in which flame B1 and/or high-temperature gas is generated from battery 10, film member 30 melts from the heat of flame B1 and/or high-temperature gas and opens the plurality of through holes 21. This makes it possible to discharge flame B1 and/or high-temperature gas from the plurality of through holes 21.

In this manner, in electronic device 1 in which battery 10 is housed without being exposed to the outside of housing 3, it is possible to discharge flame B1 and/or high-temperature gas to the outside of housing 3 at the time of abnormal heat generation while securing dustproofness and waterproofness at the time of normal use.

The plurality of through holes 21 have a slit shape having a longitudinal direction (X-direction) and a lateral direction (Y-direction) in plan view. Such a configuration makes it possible to easily discharge flame B1 and/or high-temperature gas to the outside of housing 3 at the time of abnormal heat generation while suppressing a decrease in dustproofness and waterproofness at the time of normal use. In addition, a decrease in mechanical strength of housing 3 can be suppressed. This can further improve safety.

The plurality of through holes 21 are provided at first interval P1 in the longitudinal direction and at second interval P2 smaller than first interval P1 in the lateral direction in plan view. Such a configuration makes it possible to more easily discharge flame B1 and/or high-temperature gas to the outside of housing 3 at the time of abnormal heat generation. This can further improve safety.

Battery 10 includes a plurality of battery cells 12, and the plurality of through holes 21 are provided at positions overlapping the plurality of battery cells 12 in plan view. Such a configuration makes it possible to quickly discharge flame B1 and/or high-temperature gas from through holes 21 to the outside of housing 3 when flame B1 and/or high-temperature gas is generated from battery cell 12. This can further improve safety.

Housing 3 has partition outer wall 22 that partitions the plurality of through holes 21. Partition outer wall 22 has area Sb larger than opening area Sa of through holes 21 in plan view. Such a configuration can secure the mechanical strength of housing 3.

Battery 10 has partition wall 15 disposed between adjacent battery cells 12. Partition wall 15 is disposed at a position overlapping partition outer wall 22 in plan view. Such a configuration can easily separate adjacent battery cells 12 and can further improve safety.

Film member 30 is disposed inside housing 3. Such a configuration makes it possible to dispose film member 30 closer to a heat generation source. Thus, at the time of abnormal heat generation of battery 10, film member 30 easily melts from the heat, and the plurality of through holes 21 can quickly open.

In electronic device 1, channel 40 extending to the plurality of through holes 21 is provided between battery 10 and housing 3. With such a configuration, flame B1 and/or high-temperature gas easily reaches the plurality of through holes 21 through channel 40 at the time of abnormal heat generation of battery 10. This makes it possible to easily discharge flame B1 and/or high-temperature gas from the plurality of through holes 21.

Channel 40 includes first channel 41 on the side where the plurality of through holes 21 are positioned and second channel 42 on the side opposite to the side where the plurality of through holes 21 are positioned. First channel 41 is smaller than second channel 42. Such a configuration makes it possible to make the flow velocity in first channel 41 larger than the flow velocity in second channel 42. With this configuration, the flow velocity of flame B1 and/or high-temperature gas increases in first channel 41 at the time of abnormal heat generation of battery 10, and flame B1 and/or high temperature gas is quickly discharged from the plurality of through holes 21.

Battery 10 has battery case 11 that defines an outer contour of battery 10. The melting point of film member 30 is lower than the melting point of battery case 11. Such a configuration can make film member 30 more easily melt from the heat than battery case 11. This cause film member 30 to quickly melt and flame B1 and/or high-temperature gas to be discharged from the plurality of through holes 21 at the time of abnormal heat generation of battery 10.

Film member 30 includes a film and/or an adhesive tape. Such a configuration can further improve safety. In addition, film member 30 can be easily attached to housing 3.

In the present exemplary embodiment, an example in which electronic device 1 is a laptop PC has been described, but the present invention is not limited to this configuration. For example, electronic device 1 maybe a tablet PC, a smartphone, or another information processing device.

In the present exemplary embodiment, an example in which electronic device 1 houses two batteries 10 has been described, but the present invention is not limited to this configuration. For example, electronic device 1 may house one or more batteries 10.

In the present exemplary embodiment, an example in which battery cell 12 of battery 10 is a cylindrical cell has been described, but the present invention is not limited to this configuration. For example, battery cell 12 may be a prismatic cell.

In the present exemplary embodiment, an example in which battery 10 has partition wall 15 has been described, but the present invention is not limited to this configuration. For example, battery 10 does not have to have partition wall 15.

In the present exemplary embodiment, an example in which the plurality of through holes 21 have substantially the same shape and size has been described, but the present invention is not limited to this configuration. For example, the shapes and/or sizes of the plurality of through holes 21 may be different. For example, the sizes of the plurality of through holes 21 on the central side of second housing 3 may be larger than those on an end side. This makes it possible to easily discharge flame B1 and/or high-temperature gas flowing through the central side of second housing 3 having higher airtightness from the plurality of through holes 21.

In the present exemplary embodiment, an example has been described in which the plurality of through holes 21 are provided at first interval P1 in the longitudinal direction and at second interval P2 in the lateral direction in plan view, but the present invention is not limited to this configuration. For example, the plurality of through holes 21 may be provided in a staggered manner. Alternatively, the plurality of through holes 21 may be provided at different intervals.

In the present exemplary embodiment, an example in which film member 30 is disposed inside second housing 3 has been described, but the present invention is not limited to this configuration. For example, film member 30 may be disposed outside second housing 3.

Although the present disclosure has been fully described with reference to preferable exemplary embodiments and with reference to the accompanying drawings, various changes and modifications will become apparent to those skilled in the art. Such variations and modifications are to be understood as being included within the scope of the present disclosure as set forth in the appended scope of claims unless departing from the scope of the present disclosure.

Since the present disclosure can improve safety, the present disclosure is applied to, for example, an electronic device (for example, a laptop PC, a tablet PC, or the like) in which a battery is housed inside.

What is claimed is:

1. An electronic device comprising:
a battery;
a housing that houses the battery and includes a plurality of through holes in an area where the battery is disposed; and
a film member that is disposed in the housing, closes the plurality of through holes, and melts from heat.

2. The electronic device according to claim 1, wherein
each of the plurality of through holes has a slit shape having a longitudinal direction and a lateral direction in plan view.

3. The electronic device according to claim 2, wherein
the plurality of through holes are provided at a first interval in the longitudinal direction and provided at a second interval smaller than the first interval in the lateral direction in plan view.

4. The electronic device according to claim 1, wherein
the battery includes a plurality of battery cells, and
the plurality of through holes are provided at positions overlapping the plurality of battery cells in plan view.

5. The electronic device according to claim 1, wherein
the housing includes a partition outer wall that partitions the plurality of through holes, and
the partition outer wall has an area larger than an opening area of the plurality of through holes in plan view.

6. The electronic device according to claim 5, wherein
the battery includes a partition wall disposed between two adjacent battery cells among the plurality of battery cells, and
the partition wall is disposed at a position overlapping the partition outer wall in plan view.

7. The electronic device according to claim 1, wherein
the film member is disposed inside the housing.

8. The electronic device according to claim 1, wherein
a channel extending along the plurality of through holes is provided between the battery and the housing.

9. The electronic device according to claim 8, wherein
the channel includes a first channel closer to the plurality of through holes than the battery and a second channel farther from the plurality of through holes than the battery, and
the first channel has a width smaller than a width of the second channel.

10. The electronic device according to claim 1, wherein
the battery includes a battery case defining an outer contour of the battery, and
the film member has a melting point lower than a melting point of the battery case.

11. The electronic device according to claim 1, wherein
the film member includes at least either a film or an adhesive tape.

12. The electronic device according to claim 1, wherein
the film member is made of polyethylene terephthalate, polyethylene, or polypropylene.
